(19) United States
(12) Patent Application Publication
(10) Pub. No.: US 2023/0047232 A1
(43) Pub. Date: Feb. 16, 2023

(54) Fbar Type Filter

(71) Applicant: WISOL CO., LTD., Gyeonggi-do (KR)

(72) Inventors: Chul Hwa LEE, Gyeonggi-do (KR); Jung Hoon HAN, Gyeonggi-do (KR); A Young MOON, Gyeonggi-do (KR)

(21) Appl. No.: 17/876,898

(22) Filed: Jul. 29, 2022

(30) Foreign Application Priority Data
Aug. 13, 2021 (KR) 10-2021-0107083

(51) Int. Cl. H03H 9/17; H03H 9/56; H03H 9/13

(52) U.S. Cl. CPC H03H 9/172; H03H 9/564; H03H 9/13

(57) ABSTRACT

Disclosed is a film bulk acoustic resonator (FBAR) type filter including a substrate including two or more cavities on a top surface thereof, a lower electrode formed above the substrate, a piezoelectric layer formed above the lower electrode, two or more upper electrodes formed above the piezoelectric layer, and a package layer including a wall vertically extending while surrounding a periphery of certain areas in which the cavities and the lower electrode are formed and a roof disposed above the wall while being spaced apart from the upper electrodes to seal the certain areas.

### CROSS-REFERENCE TO RELATED APPLICATION

This application claims the benefit of Korean Patent Application No. 10-2021-0107083, filed on Aug. 13, 2021, in the Korean Intellectual Property Office, the disclosure of which is incorporated herein in its entirety by reference.

### FIELD

The present invention relates to a film bulk acoustic resonator (FBAR) usable in a filter, duplexer, and the like for communication in a radio frequency (RF) band, and more particularly, to an FBAR type filter.

### BACKGROUND

Wireless mobile communication technology requires a variety of radio frequency (RF) components capable of efficiently transmitting information within a limited frequency band. Particularly, among RF components, a filter is one of essential components used in mobile communication technology and enables high-quality communication by selecting a signal needed by a user among innumerable frequency bands or by filtering a signal to be transmitted.

Currently, a dielectric filter and a surface acoustic wave (hereinafter, referred to as SAW) filter have been used most as RF filters for wireless communication. The dielectric filter has advantages such as a high dielectric constant, a low insertion loss, stability at a high temperature, high vibration resistance, and high shock resistance. However, the dielectric filter has a limitation in miniaturization and monolithic microwave integrated circuit (MMIC) which are recent trends of technology development. Also, in comparison to the dielectric filter, the SAW filter has a small size, easily processes a signal, has a simple circuit, and is manufactured using a semiconductor process so as to facilitate mass production. Also, the SAW filter has an advantage of transmitting and receiving high-grade information due to high side rejection within a passband in comparison to the dielectric filter. However, since an SAW filter process includes an exposure process using ultraviolet (UV), there is a disadvantage in which a line width of an interdigital transducer (IDT) has a limitation of about 0.5 μm. Accordingly, there is a problem in which it is impossible to cover an ultrahigh frequency band of 3 GHz or more using the SAW filter. Basically, there is a difficulty in forming an MMIC structure and a single chip on a semiconductor substrate.

In order to overcome such limitations and problems, a film bulk acoustic resonator (FBAR) filter integrated with other active devices on an existing semiconductor (Si or GaAs) substrate to completely implement a frequency control circuit as an MMIC is provided.

The FBAR is a thin film device which is low-cost, small-sized, and features high quality coefficient so as to be applicable to a wireless communication device, a military-use radar, and the like in a variety of frequency bands of 900 MHz to 10 GHz. Also, the FBAR is reduced in size as one-several hundredth of the dielectric filter and a lumped constant (LC) filter and has a very smaller insertion loss than the SAW filter. Accordingly, it is apparent that the FBAR is one of most adequate devices for an MMIC which requires high stability and a high quality coefficient.

An FBAR filter is formed by depositing zinc oxide (ZnO), aluminum nitride (AlN), or the like which is a piezoelectric-dielectric material on silicon (Si) or gallium arsenide (GaAs) which is a semiconductor substrate using an RF sputtering method and causes resonation due to a piezoelectric property. That is, the FBAR is formed by depositing a piezoelectric film between both electrodes and generates resonance by causing a bulk acoustic wave.

Previously, in order to protect an FBAR type filer including the FBAR from external surroundings, a bonding part between a filter wafer (device) and a protection wafer (cap) is packaged using a metal material through wafer bonding.

The above package structure requires a great thickness caused by use of two wafers, a silicon hole formed in the protection wafer to form a redistribution layer, and a wide bonding layer area for bonding with the filter wafer, and thus a size and a thickness of the device increase due to the structure. Also, since it is necessary to form a metal for bonding and to form a silicon via layer for forming the redistribution layer, the number of operations increases and a process becomes complicated.

### RELATED ART DOCUMENT

### Patent Document

Patent Document 0001: Korean Patent Publication No. 10-2004-0102390 (published on Dec. 8, 2004)

### SUMMARY

The present invention is directed to providing a film bulk acoustic resonator (FBAR) type filter which enables simplification of a packaging process of the FBAR filter and a decrease in a package size.

According to an aspect of the present invention, there is provided an FBAR type filter including a substrate including two or more cavities on a top surface thereof, a lower electrode formed above the substrate, a piezoelectric layer formed above the lower electrode, two or more upper electrodes formed above the piezoelectric layer, and a package layer including a wall vertically extending while surrounding a periphery of certain areas in which the cavities and the lower electrode are formed and a roof disposed above the wall while being spaced apart from the upper electrodes to seal the certain areas.

The package layer may be formed of a photosensitive polymer.

The piezoelectric layer may include an open hole formed above any one of the cavities in contact therewith and communicable with the any one cavity, and the wall may surround a periphery of the open hole.

An edge of the roof may be formed inside an edge of the wall.

The FBAR type filter may include a first distribution layer formed along a side part of one side of the package layer and having one end connected to the lower electrode and the other end connected to a top of the roof and a second distribution layer formed along a side part of the other side of the package layer and having one end connected to any one of the upper electrodes and the other end connected to the top of the roof.

According to another aspect of the present invention, there is provided an FBAR type filter including a substrate including two or more cavities on a top surface thereof, a lower electrode formed above the substrate, a piezoelectric layer formed above the lower electrode, two or more upper electrodes formed above the piezoelectric layer, and a package layer including a wall vertically extending while surrounding a periphery of certain areas in which the cavities and the lower electrode are formed and a roof disposed above the wall while being spaced apart from the upper electrodes to seal the certain areas. Here, the piezoelectric layer includes an open hole formed above any one of the cavities in contact therewith and communicable with the any one cavity, and the wall seals the open hole.

The package layer may be formed of a photosensitive polymer.

An edge of the roof may be formed inside an edge of the wall.

The FBAR type filter may include a first distribution layer formed along a side part of one side of the package layer and having one end connected to the lower electrode and the other end connected to a top of the roof and a second distribution layer formed along a side part of the other side of the package layer and having one end connected to any one of the upper electrodes and the other end connected to the top of the roof.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a plan view of an embodiment of a film bulk acoustic resonator (FBAR) type filter according to the present invention;

FIG. 2 is a vertical cross-sectional view taken along line A-A′ of the FBAR type filter shown in FIG. 1;

FIG. 3 is a vertical cross-sectional view taken along line B-B′ of the FBAR type filter shown in FIG. 1;

FIG. 4 is a plan view of another embodiment of the FBAR type filter according to the present invention;

FIG. 5 is a vertical cross-sectional view taken along line A-A′ of the FBAR type filter shown in FIG. 4; and

FIG. 6 is a vertical cross-sectional view taken along line B-B′ of the FBAR type filter shown in FIG. 4.

### DETAILED DESCRIPTION

Hereinafter, exemplary embodiments of the present invention will be described in detail with reference to the attached drawings.

The embodiments of the present invention are provided to more completely explain the present invention to one of ordinary skill in the art. The embodiments of the present invention may be changed in a variety of shapes, and the scope of the present invention is not limited to the following embodiments. The embodiments are provided to make the present disclosure more substantial and complete and to completely transfer the concept of the present invention to those skilled in the art.

The terms used herein are to explain particular embodiments and not intended to limit the present invention. As used herein, singular forms may include plural forms unless particularly defined otherwise in context. Also, as used herein, the term “and/or” includes any and all combinations or one of a plurality of associated listed items. Also, hereinafter, the embodiments of the present invention will be described with reference to the drawings which schematically illustrate the embodiments of the present invention.

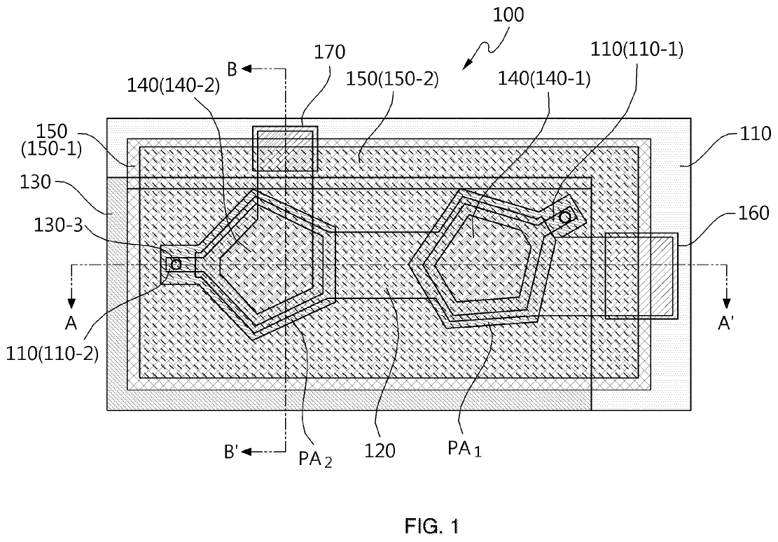

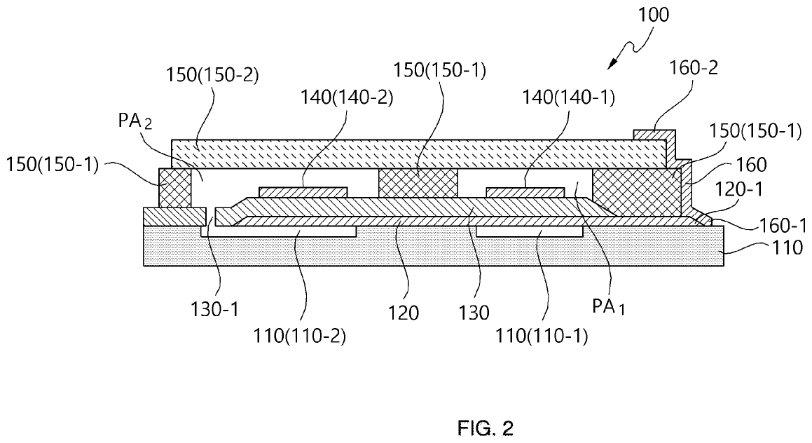

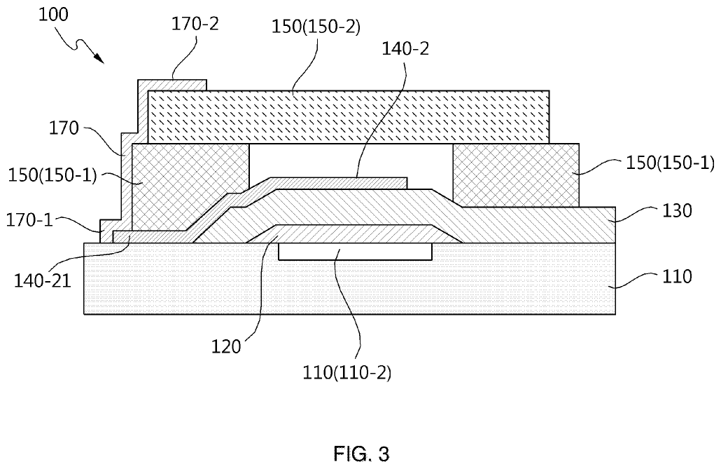

FIG. 1 is a plan view of an embodiment of a film bulk acoustic resonator (FBAR) type filter according to the present invention, FIG. 2 is a vertical cross-sectional view taken along line A-A′ of the FBAR type filter shown in FIG. 1, and FIG. 3 is a vertical cross-sectional view taken along line B-B′ of the FBAR type filter shown in FIG. 1.

Referring to FIGS. 1 to 3, an FBAR type filter 100 includes a substrate 110, a lower electrode 120, a piezoelectric layer 130, an upper electrode 140, a package layer 150, a first distribution layer 160, and a second distribution layer 170.

When an external signal is applied to a space between the lower electrode 120 and the upper electrode 140, the FBAR type filter 100 resonates with respect to a natural frequency according to a thickness of the piezoelectric layer 130 while part of electrical energy input and transferred between the two electrodes is converted into mechanical energy according to the piezoelectric effect and the mechanical energy is converted again into electrical energy.

The substrate 110 is a semiconductor substrate and may be a general silicon wafer, and preferably, a high-resistivity silicon (HRS) wafer. An insulation layer (not shown) may be formed on a top surface of the substrate 110. As the insulation layer, a thermal oxide film which is easily growable on the substrate 110 may be employed or an oxide film or a nitride film which is formed using a general deposition process such as chemical vapor deposition and the like may be selectively employed.

Also, the substrate 110 includes two or more cavities 110-1 and 110-2 on the top surface thereof. The cavities 110-1 and 110-2 are formed by forming a space portion in the substrate 110, forming the insulation layer on the space portion, depositing a sacrificial layer above the insulation layer, performing planarization through etching, and removing the sacrificial layer. Here, the sacrificial layer is formed using a material such as polysilicon, SiO₂, and the like which has excellent surface roughness and is easily formed and removed. As an example, SiO₂, PSG, PBST, BSG, or polysilicon may be used as the sacrificial layer. SiO₂, PSG, PBST, BSG, or polysilicon has excellent surface roughness and is easily formed and removed, and particularly, may be removed using dry etching in a following process.

The lower electrode 120 is formed above the substrate 110. The lower electrode 120 may be formed above the cavities 110-1 and 110-2 in the substrate 110 and surround an entirety or part of tops of the cavities 110-1 and 110-2. The lower electrode 120 is formed by depositing and pattering a certain material above the substrate 110. A material used for the lower electrode 120 is a general conductive material such as a metal and may preferably include one of aluminum (Al), tungsten (W), gold (Au), platinum (Pt), nickel (Ni), titanium (Ti), chrome (Cr), palladium (Pd), and molybdenum (Mo). The lower electrode 120 may have a thickness of 10 to 1,000 nm.

The piezoelectric layer 130 is formed above the lower electrode 120. The piezoelectric layer 130 may be formed by depositing a piezoelectric material above the lower electrode 120 and patterning the deposited piezoelectric material.

One side part of the piezoelectric layer 130 may be formed above the cavity 110-2 in direct contact therewith. As shown in FIG. 2, an open hole 130-1 which may communicate with the cavity 110-2 is formed in the one side part of the piezoelectric layer 130. The open hole 130-1 is a hole vertically passing through the piezoelectric layer 130 and is formed to be communicable with the cavity 110-2 and an air space formed above the piezoelectric layer 130.

As the piezoelectric material, aluminum nitride (AlN) or zinc oxide (ZnO) may be used. As a deposition method, a radio frequency (RF) magnetron sputtering method, evaporation method, and the like are used. The piezoelectric electrode 130 may have a thickness of 5 to 500 nm.

The upper electrode 140 is formed above the piezoelectric layer 130. The upper electrode 140 may be formed by depositing a metal film for an upper electrode above the piezoelectric layer 130 and patterning the deposited metal film. The upper electrode 140 may be formed using the same material, deposition method, and patterning method as those of the lower electrode 120. The upper electrode 140 may have a thickness of 5 to 1,000 nm.

Two or more upper electrodes 140 may be present. As shown in FIGS. 1 and 2, the upper electrodes 140 may include a first upper electrode 140-1 and a second upper electrode 140-2. The first upper electrode 140-1 may be formed above one side of the piezoelectric layer 130, and the second upper electrode 140-2 may be formed above the other side of the piezoelectric layer 130.

As shown in FIG. 1, the first upper electrode 140-1 and the second upper electrode 140-2 may be formed to be polygonal planes. Here, the second upper electrode 140-2 may be formed above the piezoelectric layer 130 while one side of the polygonal plane extends along an incline of the piezoelectric layer 130 and is formed above the substrate 110.

The package layer 150 includes a wall 150-1 and a roof 150-2. Here, the package layer 150 may be formed using a photosensitive polymer.

The wall 150-1 vertically extends while surrounding a periphery of certain areas PA1 and PA2 in which the cavities 110-1 and 110-2 and the lower electrode 120 are formed. The wall 150-1 may have a minimum height which does not allows the upper electrodes 140-1 and 140-2 moving along vibration of the piezoelectric layer to come into contact with the roof 150-2.

The wall 150-1 may surround the open hole 130-1 included in the piezoelectric layer 130. That is, the wall 150-1 may not seal the open hole 130-1 included in the piezoelectric layer 130 but surround a periphery thereof.

The roof 150-2 is disposed above the wall 150-1 while being spaced apart from the upper electrodes 140-1 and 140-2 and seals the certain areas PA1 and PA2. Here, an edge of the roof 150-2 may be formed inside an edge of the wall 150-1.

The first distribution layer 160 is formed along a side part of one side of the package layer 150. Referring to FIG. 2, one end 160-1 of the first distribution layer 160 is connected to an end 120-1 of the lower electrode 120 and the other end 160-2 of the first distribution layer 160 is connected to a top of the roof 150-2. The first distribution layer 160 may be formed of a conductive metal material.

The second distribution layer 170 is formed along a side part of the other side of the package layer 150. Referring to FIG. 3, one end 170-1 of the second distribution layer 170 is connected to an end 140-21 of the upper electrode 140-2 and the other end 170-2 of the second distribution layer 170 is connected to the top of the roof 150-2.

As shown in FIG. 3, in the second upper electrode 140-2, one side of the polygonal plane extends along an incline of the piezoelectric layer 130 and the end 140-21 of the second upper electrode 140-2 is formed above the substrate 110. Here, the end 140-21 of the second upper electrode 140-2 extends further outward than the edge of the wall 150-1 of the package layer 150 to be exposed outside. Accordingly, the one end 170-1 of the second distribution layer 170 may be connected to the end 140-21 of the second upper electrode 140-2 which is exposed outside. The second distribution layer 170 may be formed of a conductive metal material.

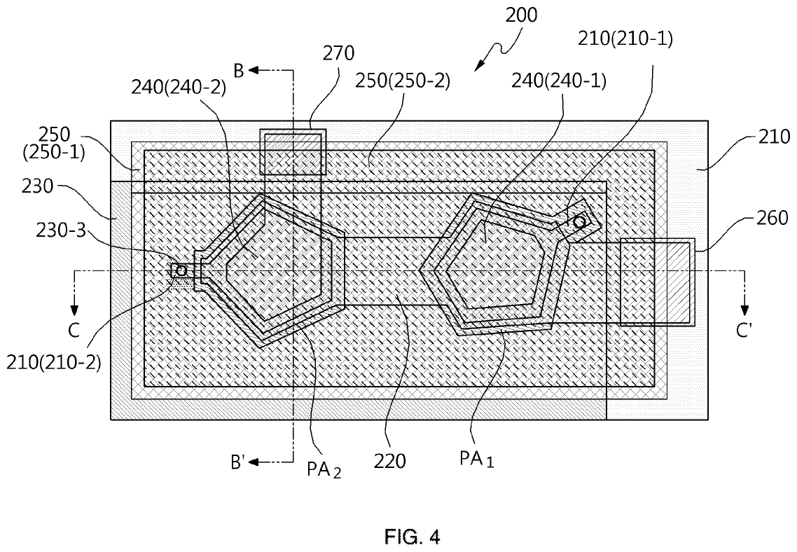

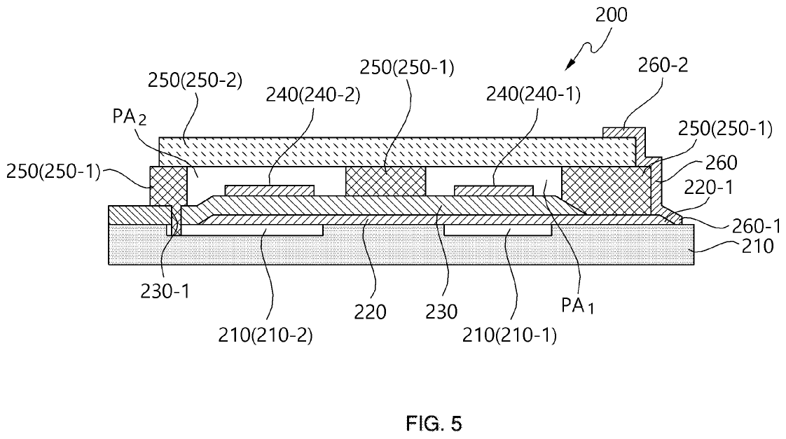

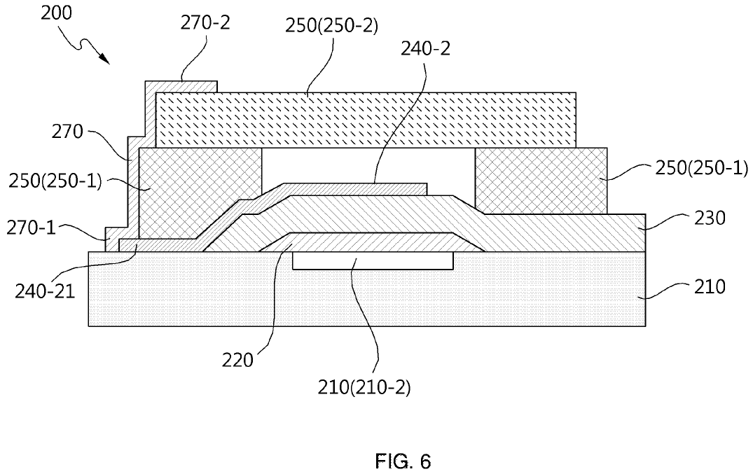

FIG. 4 is a plan view of another embodiment of the FBAR type filter according to the present invention, FIG. 5 is a vertical cross-sectional view taken along line A-A′ of the FBAR type filter shown in FIG. 4, and FIG. 6 is a vertical cross-sectional view taken along line B-B′ of the FBAR type filter shown in FIG. 4.

Referring to FIGS. 4 to 6, an FBAR type filter 200 includes a substrate 210, a lower electrode 220, a piezoelectric layer 230, an upper electrode 240, a package layer 250, a first distribution layer 260, and a second distribution layer 270.

As described above, the substrate 210 may be a general silicon wafer, and preferably, an HRS wafer. An insulation layer (not shown) may be formed on a top surface of the substrate 210.

Also, the substrate 210 includes two or more cavities 210-1 and 210-2 on the top surface thereof. The cavities 210-1 and 210-2 are formed by forming a space portion in the substrate 210, forming the insulation layer on the space portion, depositing a sacrificial layer above the insulation layer, performing planarization through etching, and removing the sacrificial layer.

The lower electrode 220 is formed above the substrate 210. The lower electrode 220 may be formed above the cavities 210-1 and 210-2 in the substrate 210 and surround an entirety or part of tops of the cavities 210-1 and 210-2. The lower electrode 220 is formed by depositing and pattering a certain material above the substrate 210. A material used for the lower electrode 220 is a general conductive material such as a metal and may preferably include one of Al, W, Au, Pt, Ni, Ti, Cr, Pd, and Mo.

The piezoelectric layer 230 is formed above the lower electrode 220. The piezoelectric layer 230 may be formed by depositing a piezoelectric material above the lower electrode 220 and patterning the deposited piezoelectric material.

One side part of the piezoelectric layer 230 may be formed above the cavity 210-2 in direct contact therewith. An open hole 230-1 which may communicate with the cavity 210-2 is formed in the one side part of the piezoelectric layer 230. The open hole 230-1 is a hole vertically passing through the piezoelectric layer 230 and is formed to be communicable with the cavity 210-2 and an air space formed above the piezoelectric layer 230. As the piezoelectric material, AlN or ZnO may be used.

The upper electrode 240 is formed above the piezoelectric layer 230. The upper electrode 240 may be formed by depositing a metal film for an upper electrode above the piezoelectric layer 230 and patterning the deposited metal film. The upper electrode 240 may be formed using the same material, deposition method, and patterning method as those of the lower electrode 220.

Two or more upper electrodes 240 may be present. As shown in FIGS. 4 and 5, the upper electrodes 240 may include a first upper electrode 240-1 and a second upper electrode 240-2.

As shown in FIG. 4, the first upper electrode 240-1 and the second upper electrode 240-2 may be formed to be polygonal planes above piezoelectric layer 230. Here, the second upper electrode 240-2 may be formed above the piezoelectric layer 230 while one side of the polygonal plane extends along an incline of the piezoelectric layer 230 and is formed above the substrate 210.

The package layer 250 includes a wall 250-1 and a roof 250-2. The package layer 250 may be formed using a photosensitive polymer.

The wall 250-1 vertically extends while surrounding a periphery of certain areas PA1 and PA2 in which the cavities 210-1 and 210-2 and the lower electrode 220 are formed. Here, the wall 250-1 may seal the open hole 230-1 included in the piezoelectric layer 230. That is, the wall 250-1 may be disposed in the open hole 230-1 which allows the cavity 210-2 to communicate with an air space formed above the piezoelectric layer 230.

The roof 250-2 is disposed above the wall 250-1 while being spaced apart from the upper electrodes 240-1 and 240-2 and seals the certain areas PA1 and PA2. Here, an edge of the roof 250-2 may be formed inside an edge of the wall 250-1.

The first distribution layer 260 is formed along a side part of one side of the package layer 250. Referring to FIG. 5, one end 260-1 of the first distribution layer 260 is connected to an end 220-1 of the lower electrode 220 and the other end 260-2 of the first distribution layer 260 is connected to a top of the roof 250-2. The first distribution layer 260 may be formed of a conductive metal material.

The second distribution layer 270 is formed along a side part of the other side of the package layer 250. Referring to FIG. 6, one end 270-1 of the second distribution layer 270 is connected to an end 240-21 of the upper electrode 240-2 and the other end 270-2 of the second distribution layer 270 is connected to the top of the roof 250-2.

As shown in FIG. 6, in the second upper electrode 240-2, one side of the polygonal plane extends along an incline of the piezoelectric layer 230 and the end 240-21 of the second upper electrode 240-2 is formed above the substrate 210. Here, the end 240-21 of the second upper electrode 240-2 extends further outward than the edge of the wall 250-1 of the package layer 250 to be exposed outside. Accordingly, the one end 270-1 of the second distribution layer 270 may be connected to the end 240-21 of the second upper electrode 240-2 which is exposed outside. The second distribution layer 270 may be formed of a conductive metal material.

According to the present invention, since the FBAR type filter includes the wall which vertically extends while surrounding a periphery of certain areas in which the cavities and the lower electrode are formed and a roof disposed above the wall while being spaced apart from the upper electrodes to seal the certain area, there are provided effects of simplifying a package structure and packaging operations of the FBAR type filter and reducing a package size in comparison to an existing package.

Although the exemplary embodiments of the present invention have been described above, it can be understood by one of ordinary skill in the art that a variety of modifications may be made without departing from the essential characteristics of the present invention. Therefore, the disclosed embodiments should be considered in an explanatory view not in a limitative view. It should be noted that the scope of the present invention is defined in the claims not in the above description and all equivalents thereof are included in the present invention.

What is claimed is:

1. A film bulk acoustic resonator (FBAR) type filter comprising:
a substrate comprising two or more cavities on a top surface thereof;
a lower electrode formed above the substrate;
a piezoelectric layer formed above the lower electrode;
two or more upper electrodes formed above the piezoelectric layer; and
a package layer including a wall vertically extending while surrounding a periphery of certain areas in which the cavities and the lower electrode are formed and a roof disposed above the wall while being spaced apart from the upper electrodes to seal the certain areas.

2. The FBAR type filter of claim 1, wherein the package layer is formed of a photosensitive polymer.

3. The FBAR type filter of claim 1, wherein the piezoelectric layer comprises an open hole formed above any one of the cavities in contact therewith and communicable with the any one cavity, and
wherein the wall surrounds a periphery of the open hole.

4. The FBAR type filter of claim 1, wherein an edge of the roof is formed inside an edge of the wall.

5. The FBAR type filter of claim 1, comprising:
a first distribution layer formed along a side part of one side of the package layer and having one end connected to the lower electrode and the other end connected to a top of the roof; and
a second distribution layer formed along a side part of the other side of the package layer and having one end connected to any one of the upper electrodes and the other end connected to the top of the roof.

6. An FBAR type filter comprising:
a substrate comprising two or more cavities on a top surface thereof;
a lower electrode formed above the substrate;
a piezoelectric layer formed above the lower electrode;
two or more upper electrodes formed above the piezoelectric layer; and
a package layer including a wall vertically extending while surrounding a periphery of certain areas in which the cavities and the lower electrode are formed and a roof disposed above the wall while being spaced apart from the upper electrodes to seal the certain areas,
wherein, the piezoelectric layer comprises an open hole formed above any one of the cavities in contact therewith and communicable with the any one cavity, and
wherein the wall seals the open hole.

7. The FBAR type filter of claim 6, wherein the package layer is formed of a photosensitive polymer.

8. The FBAR type filter of claim 6, wherein an edge of the roof is formed inside an edge of the wall.

9. The FBAR type filter of claim 6, comprising:
a first distribution layer formed along a side part of one side of the package layer and having one end connected to the lower electrode and the other end connected to a top of the roof; and
a second distribution layer formed along a side part of the other side of the package layer and having one end connected to any one of the upper electrodes and the other end connected to the top of the roof.
